(19) United States
(12) Patent Application Publication
(10) Pub. No.: US 2025/0070088 A1
(43) Pub. Date: Feb. 27, 2025

(54) SEMICONDUCTOR PACKAGE

(71) Applicant: SAMSUNG ELECTRONICS CO., LTD., SUWON-SI (KR)

(72) Inventors: JINHEE HONG, Suwon-si (KR); BU-WON KIM, Suwon-si (KR)

(21) Appl. No.: 18/660,677

(22) Filed: May 10, 2024

(30) Foreign Application Priority Data
Aug. 22, 2023 (KR) 10-2023-0109870

(51) Int. Cl. H01L 25/065; H01L 23/00

(52) U.S. Cl. CPC H01L 25/0657; H01L 24/05; H01L 24/48; H01L 2224/04042; H01L 2224/48145; H01L 2224/48227; H01L 2225/06506; H01L 2225/06562

(57) ABSTRACT

A semiconductor package includes: a substrate including a plurality of connection pads; a first semiconductor chip on the substrate and including a plurality of first data pads on an upper surface thereof; a second semiconductor chip on the first semiconductor chip and including a plurality of second data pads on an upper surface thereof; a third semiconductor chip on the second semiconductor chip and including a plurality of third data pads on an upper surface thereof; and a plurality of connection members for connecting some of the plurality of connection pads and some of the plurality of first data pads, connecting the plurality of connection pads and the plurality of second data pads, and connecting some of the plurality of second data pads and some of the plurality of third data pads.

### CROSS-REFERENCE TO RELATED APPLICATION

This application claims priority to and the benefit of Korean Patent Application No. 10-2023-0109870 filed in the Korean Intellectual Property Office on Aug. 22, 2023, the entire contents of which are herein incorporated by reference.

### BACKGROUND

### (a) Technical Field

The present disclosure relates to a semiconductor package, and more particularly to a semiconductor package including semiconductor chips connected by wiring bonding.

### (b) Discussion of Related Art

As advances in electronic products lead to increasingly small and high-performance devices, semiconductors built into the electronic products are also being improved with reduced size and high performance characteristics. Particularly, in line with the development of process technologies, semiconductors with high capacity and multiple channels are being built into the electronic products. In order to embed these semiconductors within a semiconductor package, a method for stacking semiconductor chips in a vertical direction may be used.

### SUMMARY

To reduce a length of a wire acting as a stub, semiconductor chips of an upper structure may be connected to each other by wire bonding, instead of connecting the semiconductor chips in an upper structure to a substrate by wire bonding.

An embodiment of the present disclosure, to connect semiconductor chips in the upper structure to each other by wire bonding, a semiconductor package and a manufacturing method thereof may be provided, stacking a first semiconductor chip including an X8-bit structure, a second semiconductor chip including an X16-bit structure, and a third semiconductor chip including an X8-bit structure on a substrate; connecting some of connection pads of the substrate and some of data pads of the first semiconductor chip by wire bonding; connecting the connection pads of the substrate and data pads of the second semiconductor chip by wire bonding; and connecting some of the data pads of the second semiconductor chip and some of data pads of the third semiconductor chip by wire bonding.

An embodiment of the present disclosure provides a semiconductor package including: a substrate including connection pads; a first semiconductor chip on the substrate and including first data pads on an upper surface thereof; a second semiconductor chip on the first semiconductor chip and including second data pads on an upper surface thereof; a third semiconductor chip on the second semiconductor chip and including third data pads on an upper surface thereof; and connection members connecting some of the connection pads and some of the first data pads, connecting the connection pads and the second data pads, and connecting some of the second data pads and some of the third data pads.

Another embodiment of the present disclosure provides a semiconductor package including: a substrate including connection pads; a first semiconductor chip on the substrate and including first data pads on an upper surface thereof; a second semiconductor chip on the first semiconductor chip and including second data pads on an upper surface thereof; a third semiconductor chip on the second semiconductor chip and including third data pads on an upper surface thereof; first connection members connecting the substrate and the first semiconductor chip via the connection pads and the first data pads in an X8-bit connection architecture; second connection members connecting the substrate and the second semiconductor chip via the connection pads and the second data pads in an X16-bit connection architecture; and third connection members connecting the third semiconductor chip and the second semiconductor chip via the second data pads and the third data pads in the X8-bit connection architecture.

Another embodiment of the present disclosure provides a semiconductor package including: a substrate including first connection pads and second connection pads; a first semiconductor chip on the substrate and disposed between the plurality of first connection pads and the plurality of second connection pads, the first semiconductor chip including an X8-bit structure, and the first semiconductor chip including first data pads on an upper surface thereof; a second semiconductor chip on the first semiconductor chip, the second semiconductor chip including an X16-bit structure, and the second semiconductor chip including second data pads on an upper surface thereof; a third semiconductor chip on the second semiconductor chip, the third semiconductor chip including the X8-bit structure, and the third semiconductor chip including third data pads on an upper surface thereof; a fourth semiconductor chip disposed between the first semiconductor chip and the second semiconductor chip, the fourth semiconductor chip including the X8-bit structure, and the fourth semiconductor chip including fourth data pads on an upper surface thereof; a fifth semiconductor chip on the third semiconductor chip, the fifth semiconductor chip including the X16-bit structure, and the fifth semiconductor chip including fifth data pads on an upper surface thereof; a sixth semiconductor chip on the fifth semiconductor chip, the sixth semiconductor chip including the X8-bit structure, and the sixth semiconductor chip including sixth data pads on an upper surface thereof; first connection members connecting some of the first connection pads and some of the first data pads; second connection members connecting the first connection pads and the second data pads; third connection members connecting some of the second data pads and some of the third data pads; fourth connection members connecting some of the second connection pads and some of the fourth data pads; fifth connection members connecting the second connection pads and the fifth data pads; and sixth connection members connecting some of the fifth data pads and some of the sixth data pads.

Two or more of semiconductor chips in an upper structure may be connected to each other by wire bonding, instead of connecting each of the semiconductor chips in an upper structure directly to the substrate by wire bonding.

To connect semiconductor chips in an upper structure to each other by wire bonding, a semiconductor package and a manufacturing method thereof may be provided, stacking a first semiconductor chip including an X8-bit structure, a second semiconductor chip including an X16-bit structure, and a third semiconductor chip including an X8-bit structure on a substrate; connecting some of connection pads of the substrate and some of data pads of the first semiconductor chip by wire bonding; connecting the connection pads of the substrate and data pads of the second semiconductor chip by wire bonding; and connecting some of the data pads of the second semiconductor chip and some of data pads of the third semiconductor chip by wire bonding.

Therefore, the length of one or more wires may be reduced or tuned, and a probability that the wires act as a stub may be reduced. A wire that acts as a stub may cause signal attenuation or resonant frequency nulls, which may affect signal characteristics of a semiconductor chip. In an embodiment in which the lengths of one or more of the wires may be reduced or tuned, signal characteristics of the semiconductor chip may be improved. Hence, the eye margin may be improved, and the signal quality may be improved.

### BRIEF DESCRIPTION OF THE DRAWINGS

FIG. 1 shows a sideview of a semiconductor package according to an embodiment.

FIG. 2 shows a perspective view of a semiconductor package according to an embodiment.

FIG. 3 shows a top plan view of a connection of a substrate and a first semiconductor chip according to an embodiment.

FIG. 4 shows a top plan view of a connection of a substrate and a second semiconductor chip according to an embodiment.

FIG. 5 shows a top plan view of a connection of a second semiconductor chip and a third semiconductor chip according to an embodiment.

FIG. 6 shows a top plan view of a connection of a substrate and a fourth semiconductor chip according to an embodiment.

FIG. 7 shows a top plan view of a connection of a substrate and a fifth semiconductor chip according to an embodiment.

FIG. 8 shows a top plan view of a connection of a fifth semiconductor chip and a sixth semiconductor chip according to an embodiment.

### DETAILED DESCRIPTION

The present invention will be described more fully hereinafter with reference to the accompanying drawings, in which exemplary embodiments of the invention are shown. As those skilled in the art would realize, embodiments may be modified in various different ways, all without departing from the spirit or scope of the present invention.

Parts that are irrelevant to the description may be omitted to clearly describe the present invention, and the same elements will be designated by the same reference numerals throughout the specification.

The size and thickness of each configuration shown in the drawings may be arbitrarily shown for better understanding and ease of description, but the present invention is not limited thereto.

Throughout the specification, when it is described that a part is “connected (in contact with, coupled)” to another part, the part may be “directly connected” to the other element or “connected” to the other part through a third part. Unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper surface of the object portion based on a gravitational direction.

The phrase “in a plan view” means a view of an object portion from the top, and the phrase “in a cross-sectional view” means a view from a side of a cross-section of which the object portion is vertically cut.

A semiconductor package 100 according to an embodiment will now be described with reference to accompanying drawings.

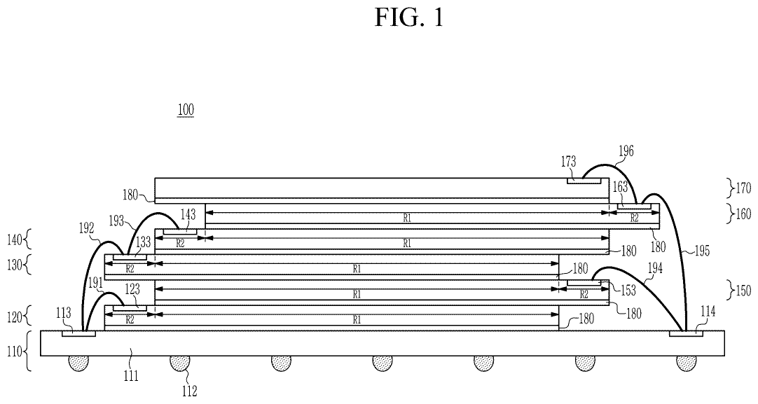

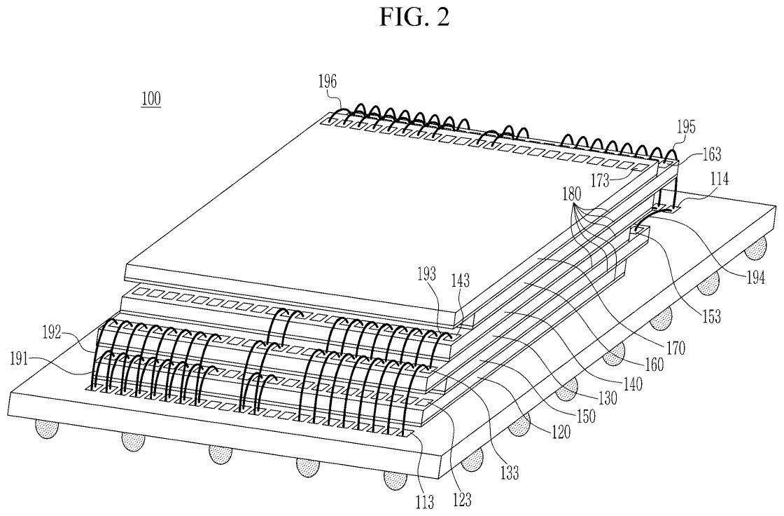

FIG. 1 shows a sideview of a semiconductor package 100 according to an embodiment. FIG. 2 shows a perspective view of a semiconductor package 100 according to an embodiment.

Referring to FIG. 1 and FIG. 2, the semiconductor package 100 may include a substrate 110, a first semiconductor chip 120, a second semiconductor chip 130, a third semiconductor chip 140, a fourth semiconductor chip 150, a fifth semiconductor chip 160, a sixth semiconductor chip 170, first connection members 191, second connection members 192, third connection members 193, fourth connection members 194, fifth connection members 195, and sixth connection members 196.

The first semiconductor chip 120, the second semiconductor chip 130, the third semiconductor chip 140, the fourth semiconductor chip 150, the fifth semiconductor chip 160, and the sixth semiconductor chip 170 may be sequentially disposed on the substrate 110. The first semiconductor chip 120, the second semiconductor chip 130, the third semiconductor chip 140, the fourth semiconductor chip 150, the fifth semiconductor chip 160, and the sixth semiconductor chip 170 may form a stack exposing first connection pads 113 and second connection pads 114 disposed on the substrate 110. The second semiconductor chip 130, the third semiconductor chip 140, the fourth semiconductor chip 150, the fifth semiconductor chip 160, and the sixth semiconductor chip 170 may form an upper stack.

The first connection members 191, the second connection members 192, the third connection members 193, the fourth connection members 194, the fifth connection members 195, and the sixth connection members 196 may each be bonding wires.

The substrate 110 may be disposed on a bottom surface of the first semiconductor chip 120. The substrate 110 may include a substrate base 111, external connection members 112, the first connection pads 113, and the second connection pads 114. In an embodiment, the substrate 110 may include an AJINOMOTO BUILD-UP FILM® (ABF) substrate. In an embodiment, the substrate 110 may include a printed circuit board (PCB). The substrate 110 may be omitted and replaced with, for example, an interposer or a semiconductor die on a wafer level. The substrate base 111 may include an insulation layer, and wiring layers and vias in the insulation layer. The external connection members 112 may be disposed on a bottom surface of the substrate base 111. The external connection member 112 may electrically connect the semiconductor package 100 to an external device. In an embodiment, the external connection member 112 may include, for example, a solder ball or a conductive bump.

The first connection pads 113 may be disposed in an upper surface of the substrate base 111. As described herein, pads disposed in a substrate, may alternatively be disposed on the substrate. For example, the first connection pads 113 disposed on an upper surface of the substrate base 111 may be disposed on a planar upper surface of the substrate base 111 or may be disposed in a recess formed in the substrate base 111. The first connection pads 113 may be electrically connected to the first connection members 191 and the second connection members 192. The second connection pads 114 may be disposed in an upper surface of the substrate base 111. The second connection pads 114 may be electrically connected to the fourth connection members 194 and the fifth connection members 195. The first connection pads 113 may be disposed adjacent to a first side of the first semiconductor chip 120, and the second connection pads 114 may be disposed adjacent to a second side. The second side may be an opposite side of the first side of the first semiconductor chip 120. In an embodiment, the first connection pads 113 and the second connection pads 114 may include at least one of copper, nickel, zinc, gold, silver, platinum, palladium, chromium, or titanium, or alloys thereof. The first connection pads 113 and the second connection pads 114 may be formed of the same material or different materials.

The first semiconductor chip 120 may be disposed on the substrate 110. The first semiconductor chip 120 may be adhered to the substrate 110 by an adhesive member 180. For example, the adhesive member 180 may be disposed on a lower surface of the first semiconductor chip 120. In an embodiment, the adhesive member 180 may include, for example, a die attach film (DAF). The first semiconductor chip 120 may include a first region R1 covered by the fourth semiconductor chip 150 and a second region R2 not covered by the fourth semiconductor chip 150. For example, the second region R2 of the first semiconductor chip 120 may be exposed on the fourth semiconductor chip 150. The first semiconductor chip 120 may include first data pads 123 in an upper surface of the second region R2. The first data pads 123 may be disposed on a planar upper surface of the first semiconductor chip 120 or may be disposed in a recess formed in the first semiconductor chip 120. The first data pads 123 may be electrically connected to the first connection members 191, respectively. The first semiconductor chip 120 may communicate with the substrate 110 and the second to sixth semiconductor chips 130, 140, 150, 160, and 170 through the first data pads 123, the first connection members 191, and the first connection pads 113. The first data pads 123 may include at least one of copper, nickel, zinc, gold, silver, platinum, palladium, chromium, or titanium, or alloys thereof.

The first semiconductor chip 120 may be a buffer chip. The buffer chip may be disposed between a memory chip and an external device (not shown). When data is transmitted and received between devices with different data processing rates, data processing units, and/or data usage times, the data may be lost because of the differences in the data processing rates, data processing units, and/or data usage times between the devices. To reduce or prevent these losses, the first semiconductor chip 120 (or the buffer chip) may be disposed between the second to sixth semiconductor chips 130, 140, 150, 160, and 170 and the external device. The first semiconductor chip 120 may temporarily store information when transmitting and receiving data between the second to sixth semiconductor chips 130, 140, 150, 160, and 170 and the external device. When transmitting the data to the second to sixth semiconductor chips 130, 140, 150, 160, and 170 or receiving data from the same, the first semiconductor chip 120 (or the buffer chip) may adjust an order of the data and sequentially pass the data to the external device.

The first semiconductor chip 120 may include an active element and a passive element in an active region. In an embodiment, the first semiconductor chip 120 may not include a memory semiconductor. In an embodiment, the first semiconductor chip 120 may include a logic circuit. In an embodiment, the logic circuit may include at least one of a test logic circuit, a signal interface circuit, an error correction code (ECC) circuit, or a frequency boosting interface (FBI) circuit. In an embodiment, the test logic circuit may include a memory built-in self-test (MBIST) and a design for test (DFT). In an embodiment, the signal interface circuit may include a physical PHY interface. In an embodiment, the first semiconductor chip 120 may error correction code (ECC)-encode and -decode the data, and may detect and correct data errors. In an embodiment, the first semiconductor chip 120 may amplify a frequency of a data signal. In an embodiment, the passive element may include at least one of a resistor, a capacitor, or an inductor.

The second semiconductor chip 130 may be disposed on the fourth semiconductor chip 150. The second semiconductor chip 130 may be adhered to the fourth semiconductor chip 150 by the adhesive member 180. For example, the adhesive member 180 may be disposed on a lower surface of the second semiconductor chip 130. In an embodiment, the adhesive member 180 may include, for example, the die attach film (DAF). The second semiconductor chip 130 may be spaced apart from the first semiconductor chip 120 in a vertical direction. The second semiconductor chip 130 may fully overlap the first semiconductor chip 120.

The second semiconductor chip 130 may include a first region R1 covered by the third semiconductor chip 140 and a second region R2 not covered by the third semiconductor chip 140. For example, the second region R2 of the second semiconductor chip 130 may be exposed from the third semiconductor chip 140. The second semiconductor chip 130 may include second data pads 133 in the upper surface of the second region R2. The second data pads 133 may be disposed on a planar upper surface of the second semiconductor chip 130 or may be disposed in a recess formed in the second semiconductor chip 130. The second data pads 133 may be electrically connected to each of the second connection members 192, respectively. The second semiconductor chip 130 may communicate with the substrate 110, the first semiconductor chip 120, and the fourth to sixth semiconductor chips 150, 160, and 170 through the second data pads 133, the second connection members 192, and the first connection pads 113. The second semiconductor chip 130 may communicate with the third semiconductor chip 140 through the second data pads 133, the third connection members 193, and the third data pads 143. The third data pads 143 may be disposed on a planar upper surface of the third semiconductor chip 140 or may be disposed in a recess formed in the third semiconductor chip 140. In an embodiment, the second data pads 133 may respectively include at least one of copper, nickel, zinc, gold, silver, platinum, palladium, chromium, or titanium, or alloys thereof.

While the adhesive member 180 is illustrated in FIG. 1 as being disposed on an entirety of the lower surface of the second semiconductor chip 130, the disclosure is not limited thereto. For example, the adhesive member 180 may be disposed in the second region R2 on an upper surface of the fourth semiconductor chip 150 and may be omitted from the first region R1 on the lower surface of the second semiconductor chip 130. Similar variations may be applied to the adhesive member 180 disposed on lower surfaces of the third semiconductor chip 140, the fourth semiconductor chip 150, the fifth semiconductor chip 160, and sixth semiconductor chip 170.

The second semiconductor chip 130 may be a memory semiconductor chip. In an embodiment, the second semiconductor chip 130 may include a volatile memory device such as a DRAM. In an embodiment, the second semiconductor chip 130 may include a nonvolatile memory chip such as a NAND flash memory.

The third semiconductor chip 140 may be disposed on the second semiconductor chip 130. The third semiconductor chip 140 may be adhered to the second semiconductor chip 130 by the adhesive member 180. For example, the adhesive member 180 may be disposed on a lower surface of the third semiconductor chip 140. In an embodiment, the adhesive member 180 may include the die attach film (DAF). The third semiconductor chip 140 may be stacked on the second semiconductor chip 130 so that to be offset in a horizontal direction away from the first connection pads 113, exposing the second data pads 133. The third semiconductor chip 140 may fully overlap the fourth semiconductor chip 150 and the sixth semiconductor chip 170.

The third semiconductor chip 140 may include a first region R1 covered by the fifth semiconductor chip 160 and a second region R2 not covered by the fifth semiconductor chip 160. For example, the second region R2 of the third semiconductor chip 140 may be exposed from the fifth semiconductor chip 160. The third semiconductor chip 140 may include third data pads 143 in the upper surface of the second region R2. The third data pads 143 may be electrically connected to each of the third connection members 193, respectively. The third semiconductor chip 140 may communicate with the substrate 110, the first semiconductor chip 120, and the fourth to sixth semiconductor chips 150, 160, and 170 through the third data pads 143, the third connection members 193, the second data pads 133, the second connection members 192, and the first connection pads 113. The third semiconductor chip 140 may communicate with the second semiconductor chip 130 through the third data pads 143, the third connection members 193, and the second data pads 133. In an embodiment, the third data pads 143 may include at least one of copper, nickel, zinc, gold, silver, platinum, palladium, chromium, or titanium, or alloys thereof.

The third semiconductor chip 140 may be a memory semiconductor chip. In an embodiment, the third semiconductor chip 140 may include a volatile memory device such as the DRAM. In an embodiment, the third semiconductor chip 140 may include a nonvolatile memory chip such as the NAND flash memory.

The fourth semiconductor chip 150 may be disposed between the first semiconductor chip 120 and the second semiconductor chip 130. The fourth semiconductor chip 150 may be adhered to the first semiconductor chip 120 by the adhesive member 180. For example, the adhesive member 180 may be disposed on a lower surface of the fourth semiconductor chip 150. In an embodiment, the adhesive member 180 may include the die attach film (DAF). The fourth semiconductor chip 150 may be stacked on the first semiconductor chip 120 to be offset in a horizontal direction away from the first connection pads 113, exposing the first data pads 123. The fourth semiconductor chip 150 may fully overlap the third semiconductor chip 140 and the sixth semiconductor chip 170.

The fourth semiconductor chip 150 may include a first region R1 covered by the second semiconductor chip 130 and a second region R2 not covered by the second semiconductor chip 130. For example, the second region R2 of the fourth semiconductor chip 150 may be exposed from the second semiconductor chip 130. The fourth semiconductor chip 150 may include fourth data pads 153 in the upper surface of the second region R2. The fourth data pads 153 may be disposed on a planar upper surface of the fourth semiconductor chip 150 or may be disposed in a recess formed in the fourth semiconductor chip 150. The fourth data pads 153 may be electrically connected to each of the fourth connection members 194, respectively. The fourth semiconductor chip 150 may communicate with the substrate 110, the first to third semiconductor chip 120, 130, and 140, the fifth semiconductor chip 160, and the sixth semiconductor chips 170 through the fourth data pads 153, the fourth connection members 194, and the second connection pads 114. The fourth data pads 153 may include at least one of copper, nickel, zinc, gold, silver, platinum, palladium, chromium, or titanium, or alloys thereof.

The fourth semiconductor chip 150 may be a memory semiconductor chip. In an embodiment, the fourth semiconductor chip 150 may include a volatile memory device such as the DRAM. In an embodiment, the fourth semiconductor chip 150 may include a nonvolatile memory chip such as the NAND flash memory.

The fifth semiconductor chip 160 may be disposed on the third semiconductor chip 140. The fifth semiconductor chip 160 may be adhered to the third semiconductor chip 140 by the adhesive member 180. For example, the adhesive member 180 may be disposed on a lower surface of the fifth semiconductor chip 160. In an embodiment, the adhesive member 180 may include the die attach film (DAF). The fifth semiconductor chip 160 may be stacked on the third semiconductor chip 140 to be offset in a horizontal direction away from the first connection pads 113, exposing the third data pads 143.

The fifth semiconductor chip 160 may include a first region R1 covered by the sixth semiconductor chip 170 and a second region R2 not covered by the sixth semiconductor chip 170. For example, the second region R2 of the fifth semiconductor chip 160 may be exposed from the sixth semiconductor chip 170. The fifth semiconductor chip 160 may include fifth data pads 163 in the upper surface of the second region R2. The fifth data pads 163 may be disposed on a planar upper surface of the fifth semiconductor chip 160 or may be disposed in a recess formed in the fifth semiconductor chip 160. The fifth data pads 163 may be electrically connected to each of the fifth connection members 195, respectively. The fifth semiconductor chip 160 may communicate with the substrate 110 and the first to fourth semiconductor chips 120, 130, 140, and 150 through the fifth data pads 163, the fifth connection members 195, and the second connection pads 114. The fifth semiconductor chip 160 may communicate with the sixth semiconductor chip 170 through the fifth data pads 163, the sixth connection members 196, and the sixth data pads 173. In an embodiment, the fifth data pads 163 may include at least one of copper, nickel, zinc, gold, silver, platinum, palladium, chromium, or titanium, or alloys thereof.

The fifth semiconductor chip 160 may be a memory semiconductor chip. In an embodiment, the fifth semiconductor chip 160 may include a volatile memory device such as the DRAM. In an embodiment, the fifth semiconductor chip 160 may include a nonvolatile memory chip such as the NAND flash memory.

The sixth semiconductor chip 170 may be disposed on the fifth semiconductor chip 160. The sixth semiconductor chip 170 may be adhered to the fifth semiconductor chip 160 by the adhesive member 180. For example, the adhesive member 180 may be disposed on a lower surface of the sixth semiconductor chip 170. In an embodiment, the adhesive member 180 may include the die attach film (DAF). The sixth semiconductor chip 170 may be stacked on the fifth semiconductor chip 160 to be offset in a horizontal direction away from the second connection pads 114, exposing the fifth data pads 163. The sixth semiconductor chip 170 may fully overlap the third semiconductor chip 140 and the fourth semiconductor chip 150.

The sixth semiconductor chip 170 may include sixth data pads 173 in its upper surface. The sixth data pads 173 may be disposed on a planar upper surface of the sixth semiconductor chip 170 or may be disposed in a recess formed in the sixth semiconductor chip 170. The sixth data pads 173 may be electrically connected to each of the sixth connection members 196, respectively. The sixth semiconductor chip 170 may communicate with the substrate 110 and the first to fourth semiconductor chips 120, 130, 140, and 150 through the sixth data pads 173, the sixth connection members 196, the fifth data pads 163, the fifth connection members 195, and the second connection pads 114. The sixth semiconductor chip 170 may communicate with the fifth semiconductor chip 160 through the sixth data pads 173, the sixth connection members 196, and the fifth data pads 163. In an embodiment, the sixth data pads 173 may include at least one of copper, nickel, zinc, gold, silver, platinum, palladium, chromium, or titanium, or alloys thereof.

The sixth semiconductor chip 170 may be a memory semiconductor chip. In an embodiment, the sixth semiconductor chip 170 may include a volatile memory device such as the DRAM. In an embodiment, the sixth semiconductor chip 170 may include a nonvolatile memory chip such as the NAND flash memory.

The first connection members 191 may be disposed between the first connection pads 113 and the first data pads 123. The first connection member 191 electrically connects the first semiconductor chip 120 the substrate 110 via the first connection pads 113 and the first data pad 123. A first end of the first connection member 191 contacts the first data pad 123, and a second end that is on an opposite side of the first end of the first connection member 191 contacts the first connection pad 113. The first end of the first connection member 191 may be electrically bonded to the first data pad 123, and the second end of the first connection member 191 may be electrically bonded to the first connection pad 113. In an embodiment, the first connection members 191 may include a bonding wire. In an embodiment, the first connection members 191 may include at least one of gold, silver, or copper, or alloys thereof.

The second connection members 192 may be disposed between the first connection pads 113 and the second data pads 133. The second connection member 192 electrically connects the second semiconductor chip 130 and the substrate 110 via the first connection pads 113 and the second data pad 133. A first end of the second connection member 192 contacts the second data pad 133, and a second end that is on an opposite side of the first end of the second connection member 192 contacts the first connection pad 113. The first end of the second connection member 192 may be electrically bonded to the second data pad 133, and the second end of the second connection member 192 may be electrically bonded to the first connection pad 113. In an embodiment, the second connection member 192 may include a bonding wire. In an embodiment, the second connection member 192 may include at least one of gold, silver, or copper, or alloys thereof.

The third connection members 193 may be disposed between the second data pads 133 and the third data pads 143. The third connection member 193 electrically connects the third semiconductor chip 140 and the second semiconductor chip 130 via the second data pads 133 and the third data pad 143. A first end of the third connection member 193 contacts the third data pad 143, and a second end that is on an opposite side of the first end of the third connection member 193 contacts the second data pad 133. In an embodiment, the third connection member 193 may include a bonding wire. The first end of the third connection member 193 may be electrically bonded to the third data pad 143, and the second end of the third connection member 193 may be electrically bonded to the second data pad 133. In an embodiment, the third connection member 193 may include at least one of gold, silver, or copper, or alloys thereof.

The fourth connection members 194 may be disposed between the second connection pads 114 and the fourth data pads 153. The fourth connection member 194 electrically connects the fourth semiconductor chip 150 and the substrate 110 via the second connection pads 114 and the fourth data pad 153. A first end of the fourth connection member 194 contacts the fourth data pad 153, and a second end that is on an opposite side of the first end of the fourth connection member 194 contacts the second connection pad 114. In an embodiment, the fourth connection member 194 may include a bonding wire. The first end of the fourth connection member 194 may be electrically bonded to the fourth data pad 153, and the second end of the fourth connection member 194 may be electrically bonded to the second connection pad 114. In an embodiment, the fourth connection member 194 may include at least one of gold, silver, or copper, or alloys thereof.

The fifth connection members 195 may be disposed between the second connection pads 114 and the fifth data pads 163. The fifth connection member 195 electrically connects the fifth semiconductor chip 160 and the substrate 110 via the second connection pads 114 and the fifth data pad 163. A first end of the fifth connection member 195 contacts the fifth data pad 163, and a second end that is on an opposite side of the first end of the fifth connection member 195 contacts the second connection pad 114. In an embodiment, the fifth connection member 195 may include a bonding wire. The first end of the fifth connection member 195 may be electrically bonded to the fifth data pad 163, and the second end of the fifth connection member 195 may be electrically bonded to the second connection pad 114. In an embodiment, the fifth connection member 195 may include at least one of gold, silver, or copper, or alloys thereof.

The sixth connection members 196 may be disposed between the fifth data pads 163 and the sixth data pads 173. The sixth connection member 196 electrically connects the sixth semiconductor chip 170 and the fifth semiconductor chip 160 via the fifth data pad 163 and the sixth data pad 173. A first end of the sixth connection member 196 contacts the sixth data pad 173, and a second end that is on an opposite side of the first end of the sixth connection member 196 contacts the fifth data pad 163. In an embodiment, the sixth connection member 196 may include a bonding wire. The first end of the sixth connection member 196 may be electrically bonded to the sixth data pad 173, and the second end of the sixth connection member 196 may be electrically bonded to the fifth data pad 163. In an embodiment, the sixth connection member 196 may include at least one of gold, silver, or copper, or alloys thereof.

According to a conventional alternately stacking the semiconductor chips and connections between a semiconductor chip and the substrate by wire bonding, the wire connected between the semiconductor chip that corresponds to an upper structure and the substrate becomes relatively longer than the wire connected to the semiconductor chip that corresponds to a lower structure. In some cases, the longer wire may act as a stub, and the faster the semiconductor chip operates in the alternately stacked structure, the more the semiconductor chip may be impacted by signal resonances. This may reduce an eye margin characteristic, and may deteriorate a signal quality. Note that the eye margin characteristic may reveal various properties of an electrical signal in an eye diagram, including for example, rise and fall times, intersymbol interference, noise, or jitter.

According to the present disclosure, the second semiconductor chip 130 may be offset from the third semiconductor chip 140 exposing the second data pads 133 of the second semiconductor chip 130, which may be directly connected to the third data pads 143 of the third semiconductor chip 140 by wire bonding, and the fifth semiconductor chip 160 may be offset from the sixth semiconductor chip 170 exposing the fifth data pads 163 of the fifth semiconductor chip 160, which may be directly connected to the sixth data pads 173 of the sixth semiconductor chip 170 by wire bonding.

In an embodiment, the lengths of one or more of the wires may be reduced or tuned, which may reduce a probability that the wires act as a stub. A wire that acts as a stub may cause resonant frequency nulls, which may affect signal characteristics of a semiconductor chip. In an embodiment in which the lengths of one or more of the wires may be reduced or tune, signal characteristics of the semiconductor chip may be improved. Hence, the eye margin may be improved, and the signal quality may be improved.

According to the present disclosure, the second semiconductor chip 130 and the third semiconductor chip 140 may be directly wire-bonded. In this instance, the fourth semiconductor chip 150 disposed below the second semiconductor chip 130 may be disposed to be offset in direction away from the first connection pad 113 on the first semiconductor chip 120 so the second semiconductor chip 130 may be disposed to protrude to be nearer the first connection pad 113 than the fourth semiconductor chip 150. When the second semiconductor chip 130 may be disposed on the fourth semiconductor chip 150 to protrude to be nearer the first connection pad 113 than the fourth semiconductor chip 150, the length of the bonding wire for connecting the second data pads 133 of the second semiconductor chip 130 and the first connection pads 113 of the substrate 110 may be reduced, compared to the case when the second semiconductor chip 130 may be disposed on the fourth semiconductor chip 150 to be offset in direction away from the first connection pad 113.

The fifth semiconductor chip 160 and the sixth semiconductor chip 170 may be directly wire-bonded. In this instance, as the third semiconductor chip 140 disposed below the fifth semiconductor chip 160 may be disposed to be offset in direction away from the second connection pad 114, the fifth semiconductor chip 160 may be disposed to protrude to be nearer the second connection pad 114 than the third semiconductor chip 140. When the fifth semiconductor chip 160 may be disposed on the third semiconductor chip 140 to protrude to be nearer the second connection pad 114 than the third semiconductor chip 140, the length of the wire bonding for connecting the fifth data pads 163 of the fifth semiconductor chip 160 and the second connection pads 114 of the substrate 110 may be reduced, compared to the case when the fifth semiconductor chip 160 may be disposed on the third semiconductor chip 140 to be offset in direction away from the second connection pad 114.

In an embodiment, the lengths of one or more of the wires may be reduced or tuned, and a probability that the wires act as a stub may be reduced. A wire that acts as a stub may cause signal attenuation or resonant frequency nulls, which may affect signal characteristics of a semiconductor chip. In an embodiment in which the lengths of one or more of the wires may be reduced or tuned, signal characteristics of the semiconductor chip may be improved. Hence, the eye margin may be improved, and the signal quality may be improved.

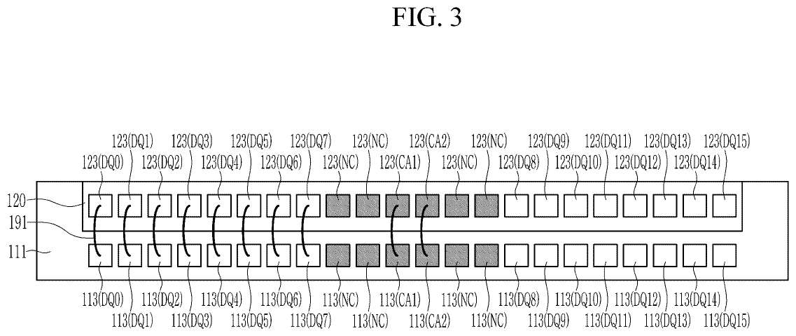

FIG. 3 to FIG. 8 show top plan views of connections between a substrate 110 and first to sixth semiconductor chips 120, 130, 140, 150, 160, and 170. The first to sixth semiconductor chips 120, 130, 140, 150, 160, and 170 may support multiple connection architectures. The first to sixth semiconductor chips 120, 130, 140, 150, 160, and 170 may support a first connection architecture having N-connections and a second connection architecture having M-connection structures, where N and M are different integers. For example, the first to sixth semiconductor chips 120, 130, 140, 150, 160, and 170 may support the X8-bit structure or the X16-bit structure. In an embodiment, the first to sixth semiconductor chips 120, 130, 140, 150, 160, and 170 may be configured to support both the X8-bit structure and the X16-bit structure. Therefore, the first to sixth semiconductor chips 120, 130, 140, 150, 160, and 170 may include a predetermined number of first to sixth data pads 123, 133, 143, 153, 163, and 173 usable in the X8-bit structure and the X16-bit structure.

FIG. 3 shows a top plan view of a connection of a substrate 110 and a first semiconductor chip 120.

Referring to FIG. 3, the first semiconductor chip 120 may include first data pads 123 (DQ0-DQ15), first CA pads 123 (CA1-CA2), and first NC pads 123 (NC) on its upper surface, where NC indicates pads that may not be wire-bonded. The CA pads and the NC pads may be auxiliary pads. In an embodiment, CA pads may be, for example, command/address pads. In an embodiment the NC pads may include, for example, a ground pad for applying a ground voltage, and a power pad for applying a power voltage.

The first semiconductor chip 120 may have the X8-bit structure. The eight first data pads 123 (DQ0-DQ7) of the first data pads 123 (DQ0-DQ15) of the first semiconductor chip 120 may be electrically connected to the eight first DQ connection pads 113 (DQ0-DQ7) of the substrate 110 through the first connection members 191. The first data pads 123 (DQ0-DQ7) of the first data pads 123 (DQ0-DQ15) of the first semiconductor chip 120 may input data signals to the first semiconductor chip 120 from the substrate 110, and may output the data signal to the substrate 110 from the first semiconductor chip 120. The eight first data pads 123 (DQ8-DQ15) of the first data pads 123 (DQ0-DQ15) of the first semiconductor chip 120 may not be wire-bonded. The eight first data pads 123 (DQ8-DQ15) that are not wire-bonded may be referred to as non-functional pads (NFP). The eight first data pads 123 (DQ8-DQ15) that are not wire-bonded from among the first data pads 123 (DQ0-DQ15) of the first semiconductor chip 120 may not be connected to the substrate 110, the second semiconductor chip 130 or the third semiconductor chip 140. In an embodiment, the first semiconductor chip 120 may have the X8-bit connection architecture connecting the first semiconductor chip 120 to the substrate 110.

The first CA pads 123 (CA1-CA2) of the first semiconductor chip 120 may be electrically connected to the first CA connection pads 113 (CA1-CA2) of the substrate 110 through the first connection members 191, respectively, and may input/output command signals and address signals. The command signals may include data strobe signals (DQS), data mask signals (DQM), chip select signals (CS), clock signals (CLK), write enable (WE) signals, RAS signals, and CAS signals.

The first NC pads 123 (NC) of the first semiconductor chip 120 may not be wire-bonded. For example, the first NC pads 123 (NC) of the first semiconductor chip 120 may include a ground pad for applying a ground voltage, and a power pad for applying a power voltage.

The substrate 110 may include first connection pads 113 on an upper surface of the substrate base 111. The first connection pads 113 may include first DQ connection pads 113 (DQ0-DQ15), first CA connection pads 113 (CA1-CA2), and first NC connection pads 113 (NC).

The eight first DQ connection pads 113 (DQ0-DQ7) of the first DQ connection pads 113 (DQ0-DQ15) of the substrate 110 may be electrically connected to each of the first data pads 123 (DQ0-DQ7) of the first semiconductor chip 120 through the first connection members 191, respectively. The eight first DQ connection pads 113 (DQ8-DQ15) of the first DQ connection pads 113 (DQ0-DQ15) may not be wire-bonded to the eight first data pads 123 (DQ8-DQ15) of the first semiconductor chip 120. The eight first DQ connection pads 113 (DQ8-DQ15) of the first DQ connection pads 113 (DQ0-DQ15) may be non-functional pads (NFPs) with respect to the eight first data pads 123 (DQ8-DQ15) of the first semiconductor chip 120.

The first CA connection pads 113 (CA1-CA2) of the substrate 110 may be electrically connected to the first CA pads 123 (CA1-CA2) of the first semiconductor chip 120 through the first connection members 191. The first NC connection pads 113 (NC) of the substrate 110 may not be wire-bonded. The substrate 110 may include a ground pad for applying a ground voltage, and a power pad for applying a power voltage.

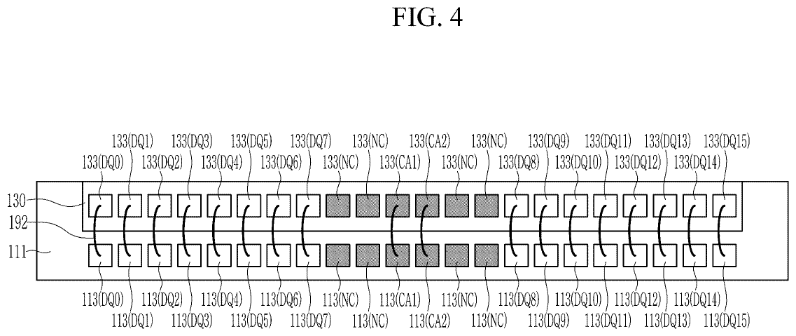

FIG. 4 shows a top plan view of a connection of a substrate 110 and a second semiconductor chip 130.

Referring to FIG. 4, the second semiconductor chip 130 may include second data pads 133 (DQ0-DQ15), second CA pads 133 (CA1-CA2), and second NC pads 133 (NC) on its upper surface, where NC indicates pads that are not wire-bonded.

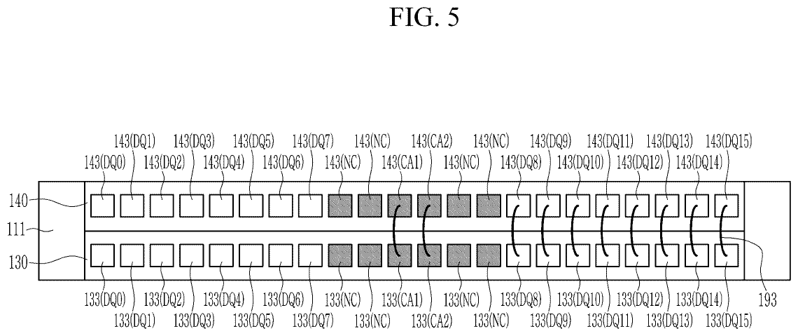

The second semiconductor chip 130 may have the X16-bit structure. The second semiconductor chip 130 has a function as a medium for connecting the substrate 110 and the third semiconductor chip 140. The second semiconductor chip 130 is electrically connected to the substrate 110 and the third semiconductor chip 140. The sixteen second data pads 133 (DQ0-DQ15) of the second semiconductor chip 130 may be connected to each of the sixteen first DQ connection pads 113 (DQ0-DQ15) of the substrate 110 through the second connection members 192, respectively. The second data pads 133 (DQ0-DQ15) of the second semiconductor chip 130 may input data signals to the second semiconductor chip 130 from the substrate 110, and may output the data signals to the substrate 110 from the second semiconductor chip 130. Referring to FIG. 5, the eight second data pads 133 (DQ8-DQ15) of the second data pads 133 (DQ0-DQ15) of the second semiconductor chip 130 may be connected to each of the eight third data pads 143 (DQ8-DQ15) of the third data pads 143 (DQ0-DQ15) of the third semiconductor chip 140 through the third connection members 193, respectively. The second data pads 133 (DQ8-DQ15) of the second data pads 133 (DQ0-DQ15) may output the data signals to the third semiconductor chip 140 from the second semiconductor chip 130, and may input the data signals to the second semiconductor chip 130 from the third semiconductor chip 140. In an embodiment, the second semiconductor chip 130 may have the X16-bit connection architecture connecting the second semiconductor chip 130 to the substrate 110.

The second CA pads 133 (CA1-CA2) of the second semiconductor chip 130 may be electrically connected to each of the first CA connection pads 113 (CA1-CA2) of the substrate 110 through the second connection members 192, respectively, and may input/output command signals and address signals. Referring to FIG. 5, the second CA pads 133 (CA1-CA2) of the second semiconductor chip 130 may be electrically connected to each of the third CA pads 143 (CA1-CA2) of the third semiconductor chip 140 through the third connection members 193, respectively, and input/output the command signals and the address signals.

The first NC pads 133 (NC) of the second semiconductor chip 130 may not be wire-bonded. The second semiconductor chip 130 may include a ground pad for applying a ground voltage, and a power pad for applying a power voltage.

The first DQ connection pads 113 (DQ0-DQ15) of the substrate 110 may be electrically connected to the second data pads 133 (DQ0-DQ15) of the second semiconductor chip 130 through the second connection members 192.

The first CA connection pads 113 (CA1-CA2) of the substrate 110 may be electrically connected to each of the second CA pads 133 (CA1-CA2) of the second semiconductor chip 130 through the second connection members 192, respectively. The first NC connection pads 113 (NC) of the substrate 110 may not be wire-bonded.

FIG. 5 shows a top plan view of a connection of a second semiconductor chip 130 and a third semiconductor chip 140.

Referring to FIG. 5, the third semiconductor chip 140 may include third data pads 143 (DQ0-DQ15), third CA pads 143 (CA1-CA2), and third NC pads 143 (NC) on the upper surface. The third NC pads 143 (NC) may not be wire-bonded.

The third semiconductor chip 140 may have the X8-bit structure. The eight third data pads 143 (DQ8-DQ15) of the third data pads 143 (DQ0-DQ15) of the third semiconductor chip 140 may be electrically connected to each of the eight second data pads 133 (DQ8-DQ15) of the second data pads 133 (DQ0-DQ15) of the second semiconductor chip 130 through the third connection members 193, respectively. The third data pads 143 (DQ8-DQ15) of the third data pads 143 (DQ0-DQ15) of the third semiconductor chip 140 may input the data signals to the third semiconductor chip 140 from the second semiconductor chip 130, and may output the data signals to the second semiconductor chip 130 from the third semiconductor chip 140. The eight third data pads 143 (DQ0-DQ7) of the third data pads 143 (DQ0-DQ15) of the third semiconductor chip 140 may not be wire-bonded. The eight third data pads 143 (DQ0-DQ7) of the third data pads 143 (DQ0-DQ15) of the third semiconductor chip 140 may be non-functional pads (NFP). The eight third data pads 143 (DQ0-DQ7) that are not wire-bonded from among the third data pads 143 (DQ0-DQ15) of the third semiconductor chip 140 may not be connected to the first semiconductor chip 120 or the second semiconductor chip 130. In an embodiment, the third semiconductor chip 140 may have the X8-bit connection architecture connecting the third semiconductor chip 140 to the second semiconductor chip 130.

The third CA pads 143 (CA1-CA2) of the third semiconductor chip 140 may be electrically connected to each of the second CA pads 133 (CA1-CA2) of the second semiconductor chip 130 through the third connection members 193, respectively, and may input/output command signals and address signals.

The third NC pads 143 (NC) of the third semiconductor chip 140 may not be wire-bonded. The third semiconductor chip 140 may include a ground pad for applying a ground voltage, and a power pad for applying a power voltage.

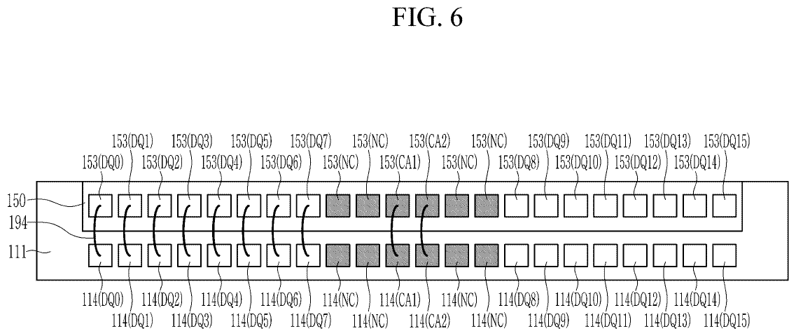

FIG. 6 shows a top plan view of a connection of a substrate 110 and a fourth semiconductor chip 150.

Referring to FIG. 6, the fourth semiconductor chip 150 may include fourth data pads 153 (DQ0-DQ15), fourth CA pads 153 (CA1-CA2), and fourth NC pads 153 (NC) on the upper surface. The fourth NC pads 153 (NC) may not be wire-bonded.

The fourth semiconductor chip 150 may have the X8-bit structure. The eight fourth data pads 153 (DQ0-DQ7) of the fourth data pads 153 (DQ0-DQ15) of the fourth semiconductor chip 150 may be electrically connected to each of the eight second DQ connection pads 114 (DQ0-DQ7) of the substrate 110 through the fourth connection members 194, respectively. The fourth data pads 153 (DQ0-DQ7) of the fourth data pads 153 (DQ0-DQ15) of the fourth semiconductor chip 150 input the data signals to the fourth semiconductor chip 150 from the substrate 110, and output the data signals to the substrate 110 from the fourth semiconductor chip 150. The eight fourth data pads 153 (DQ8-DQ15) of the fourth data pads 153 (DQ0-DQ15) of the fourth semiconductor chip 150 may not be wire-bonded. The eight fourth data pads 153 (DQ8-DQ15) of the fourth data pads 153 (DQ0-DQ15) of the fourth semiconductor chip 150 may be non-functional pads (NFP). The eight fourth data pads 153 (DQ8-DQ15) that are not wire-bonded from among the fourth data pads 153 (DQ0-DQ15) of the fourth semiconductor chip 150 may not be connected to the fifth semiconductor chip 160 or the sixth semiconductor chip 170.

The fourth CA pads 153 (CA1-CA2) of the fourth semiconductor chip 150 may be electrically connected to each of the second CA connection pads 114 (CA1-CA2) of the substrate 110 through the fourth connection members 194, respectively, and may input/output command signals and address signals.

The fourth NC pads 153 (NC) of the fourth semiconductor chip 150 may not be wire-bonded. The fourth semiconductor chip 150 may include a ground pad for applying a ground voltage, and a power pad for applying a power voltage.

The substrate 110 may include second connection pads 114 on an upper surface of the substrate base 111. The second connection pads 114 may include second DQ connection pads 114 (DQ0-DQ15), second CA connection pads 114 (CA1-CA2), and second NC connection pads 114 (NC).

The second DQ connection pads 114 (DQ0-DQ7) of the second DQ connection pads 114 (DQ0-DQ15) of the substrate 110 may be electrically connected to each of the fourth data pads 153 (DQ0-DQ7) of the fourth semiconductor chip 150 through the fourth connection members 194, respectively. The eight second DQ connection pads 114 (DQ8-DQ15) of the second DQ connection pads 114 (DQ0-DQ15) may not be wire-bonded to the eight fourth data pads 153 (DQ8-DQ15) of the fourth semiconductor chip 150. The eight second DQ connection pads 114 (DQ8-DQ15) of the second DQ connection pads 114 (DQ0-DQ15) may be non-functional pads (NFP) with respect to the eight fourth data pads 153 (DQ8-DQ15) of the fourth semiconductor chip 150.

The second CA connection pads 114 (CA1-CA2) of the substrate 110 may be electrically connected to each of the fourth CA pads 153 (CA1-CA2) of the fourth semiconductor chip 150 through the fourth connection members 194, respectively. The second NC connection pads 114 (NC) of the substrate 110 may not be wire-bonded. The substrate 110 may include a ground pad for applying a ground voltage, and a power pad for applying a power voltage.

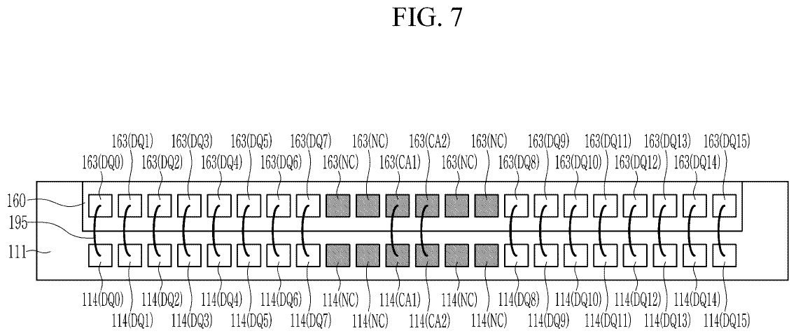

FIG. 7 shows a top plan view of a connection of a substrate 110 and a fifth semiconductor chip 160.

Referring to FIG. 7, the fifth semiconductor chip 160 may include fifth data pads 163 (DQ0-DQ15), fifth CA pads 163 (CA1-CA2), and fifth NC pads 163 (NC) on the upper surface. The fifth NC pads 163 (NC) may not be wire-bonded.

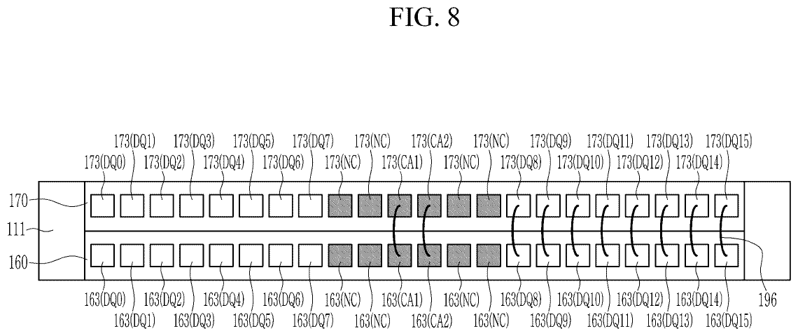

The fifth semiconductor chip 160 may have the X16-bit structure. The fifth semiconductor chip 160 has a function as a medium for connecting the substrate 110 and the sixth semiconductor chip 170. The fifth data pads 163 (DQ0-DQ15) of the fifth semiconductor chip 160 may be electrically connected to the substrate 110 and the sixth semiconductor chip 170. The sixteen fifth data pads 163 (DQ0-DQ15) of the fifth semiconductor chip 160 may be electrically connected to each of the sixteen second DQ connection pads 114 (DQ0-DQ15) of the substrate 110 through the fifth connection members 195, respectively. The fifth data pads 163 (DQ0-DQ15) of the fifth semiconductor chip 160 may input data signals to the fifth semiconductor chip 160 from the substrate 110, and may output the data signals to the substrate 110 from the fifth semiconductor chip 160. Referring to FIG. 8, the eight fifth data pads 163 (DQ8-DQ15) of the fifth data pads 163 (DQ0-DQ15) of the fifth semiconductor chip 160 may be electrically connected to each of the eight sixth data pads 173 (DQ8-DQ15) of the sixth data pads 173 (DQ0-DQ15) of the sixth semiconductor chip 170 through the sixth connection members 196, respectively. The fifth data pads 163 (DQ8-DQ15) of the fifth data pads 163 (DQ0-DQ15) of the fifth semiconductor chip 160 output data signals to the sixth semiconductor chip 170 from the fifth semiconductor chip 160, and input the data signals to the fifth semiconductor chip 160 from the sixth semiconductor chip 170.

The fifth CA pads 163 (CA1-CA2) of the fifth semiconductor chip 160 may be electrically connected to each of the second CA connection pads 114 (CA1-CA2) through the fifth connection members 195, respectively, and may input/output command signals and address signals. Referring to FIG. 8, the fifth CA pads 163 (CA1-CA2) of the fifth semiconductor chip 160 may be electrically connected to each of the sixth CA pads 173 (CA1-CA2) of the sixth semiconductor chip 170 through the sixth connection members 196, respectively, and may input/output command signals and address signals.

The fifth NC pads 163 (NC) of the fifth semiconductor chip 160 may not be wire-bonded. The fifth semiconductor chip 160 may include a ground pad for applying a ground voltage, and a power pad for applying a power voltage.

The second DQ connection pads 114 (DQ0-DQ15) of the substrate 110 may be electrically connected to the fifth data pads 163 (DQ0-DQ15) of the fifth semiconductor chip 160 through the fifth connection members 195.

The second CA connection pads 114 (CA1-CA2) of the substrate 110 may be electrically connected to each of the fifth CA pads 163 (CA1-CA2) of the fifth semiconductor chip 160 through the fifth connection members 195, respectively. The second NC connection pads 114 (NC) of the substrate 110 may not be wire-bonded.

FIG. 8 shows a top plan view of a connection of a fifth semiconductor chip 160 and a sixth semiconductor chip 170.

Referring to FIG. 8, the sixth semiconductor chip 170 may include sixth data pads 173 (DQ0-DQ15), sixth CA pads 173 (CA1-CA2), and sixth NC pads 173 (NC) on the upper surface. The sixth NC pads 173 (NC) may not be wire-bonded.

The sixth semiconductor chip 170 may have the X8-bit structure. The eight sixth data pads 173 (DQ8-DQ15) of the sixth data pads 173 (DQ0-DQ15) of the sixth semiconductor chip 170 may be electrically connected to each of the eight fifth data pads 163 (DQ8-DQ15) of the fifth data pads 163 (DQ0-DQ15) of the fifth semiconductor chip 160 through the sixth connection members 196, respectively. The sixth data pads 173 (DQ8-DQ15) of the sixth data pads 173 (DQ0-DQ15) of the sixth semiconductor chip 170 may input data signals to the sixth semiconductor chip 170 from the fifth semiconductor chip 160, and may output the data signals to the fifth semiconductor chip 160 from the sixth semiconductor chip 170. The eight sixth data pads 173 (DQ0-DQ7) of the sixth data pads 173 (DQ0-DQ15) of the sixth semiconductor chip 170 may not be wire-bonded. The eight sixth data pads 173 (DQ0-DQ7) of the sixth data pads 173 (DQ0-DQ15) of the sixth semiconductor chip 170 may be non-functional pads (NFP). The eight sixth data pads 173 (DQ0-DQ7) that are not wire-bonded from among the sixth data pads 173 (DQ0-DQ15) of the sixth semiconductor chip 170 may not be connected to the fourth semiconductor chip 150 or the fifth semiconductor chip 160.

The sixth CA pads 173 (CA1-CA2) of the sixth semiconductor chip 170 may be electrically connected to each of the fifth CA pads 163 (CA1-CA2) of the fifth semiconductor chip 160 through the sixth connection members 196, respectively and may input/output command signals and address signals.

The sixth NC pads 173 (NC) of the sixth semiconductor chip 170 may not be wire-bonded. The sixth semiconductor chip 170 may include a ground pad for applying a ground voltage, and a power pad for applying a power voltage.

While this disclosure has been described in connection with what is presently considered to be practical embodiments, it is to be understood that the disclosure is not limited thereto, and the disclosure is intended to cover various modifications and equivalent arrangements included within the spirit and scope of the appended claims.

What is claimed is:

1. A semiconductor package comprising:
a substrate including a plurality of connection pads;
a first semiconductor chip on the substrate and including a plurality of first data pads on an upper surface thereof;
a second semiconductor chip on the first semiconductor chip and including a plurality of second data pads on an upper surface thereof;
a third semiconductor chip on the second semiconductor chip and including a plurality of third data pads on an upper surface thereof; and
a plurality of connection members connecting some of the plurality of connection pads and some of the plurality of first data pads, connecting the plurality of connection pads and the plurality of second data pads, and connecting some of the plurality of second data pads and some of the plurality of third data pads.

2. The semiconductor package of claim 1, wherein
the second semiconductor chip is spaced apart from the first semiconductor chip in a vertical direction, and
the third semiconductor chip is offset from the second semiconductor chip in a horizontal direction.

3. The semiconductor package of claim 1, wherein
the first semiconductor chip and the third semiconductor chip each include an X8-bit structure, respectively, and
a second semiconductor chip includes an X16-bit structure.

4. The semiconductor package of claim 1, wherein
the first semiconductor chip, the second semiconductor chip, and the third semiconductor chip each further include a plurality of auxiliary pads, and
some of the plurality of auxiliary pads of each of the first semiconductor chip, the second semiconductor chip, and the third semiconductor chip are command/address pads.

5. The semiconductor package of claim 1, wherein
the first semiconductor chip includes a buffer chip, and
the second semiconductor chip and the third semiconductor chip each include a memory semiconductor chip, respectively.

6. A semiconductor package comprising:
a substrate including a plurality of connection pads;
a first semiconductor chip on the substrate and including a plurality of first data pads on an upper surface thereof;
a second semiconductor chip on the first semiconductor chip and including a plurality of second data pads on an upper surface thereof;
a third semiconductor chip on the second semiconductor chip and including a plurality of third data pads on an upper surface thereof;
a plurality of first connection members connecting the substrate and the first semiconductor chip via the plurality of connection pads and the plurality of first data pads in an X8-bit connection architecture;
a plurality of second connection members connecting the substrate and the second semiconductor chip via the plurality of connection pads and the plurality of second data pads in an X16-bit connection architecture; and
a plurality of third connection members connecting the third semiconductor chip and the second semiconductor chip via the plurality of second data pads and the plurality of third data pads in the X8-bit connection architecture.

7. The semiconductor package of claim 6, wherein
the plurality of first connection members are connected to eight first data pads of the plurality of first data pads,
the plurality of second connection members are connected to sixteen second data pads of the plurality of second data pads, and
the plurality of third connection members are connected to eight third data pads of the plurality of third data pads.

8. The semiconductor package of claim 6, wherein
the second semiconductor chip is spaced apart from the first semiconductor chip in a vertical direction by a fourth semiconductor chip offset from the second semiconductor chip in a horizontal direction, and
the third semiconductor chip is offset from the second semiconductor chip in the horizontal direction.

9. The semiconductor package of claim 6, wherein
the plurality of first data pads include a plurality of non-functional pads.

10. The semiconductor package of claim 6, wherein
the plurality of third data pads include a plurality of non-functional pads.

11. The semiconductor package of claim 6, wherein
the first semiconductor chip, the second semiconductor chip, and the third semiconductor chip each further include a plurality of auxiliary pads, and
some of the plurality of auxiliary pads of each of the first semiconductor chip, the second semiconductor chip, and the third semiconductor chip are command/address pads.

12. A semiconductor package comprising:
a substrate including a plurality of first connection pads and a plurality of second connection pads;
a first semiconductor chip on the substrate and disposed between the plurality of first connection pads and the plurality of second connection pads, the first semiconductor chip including an X8-bit structure, and the first semiconductor chip including a plurality of first data pads on an upper surface thereof;
a second semiconductor chip on the first semiconductor chip, the second semiconductor chip including an X16-bit structure, and the second semiconductor chip including a plurality of second data pads on an upper surface thereof;
a third semiconductor chip on the second semiconductor chip, the third semiconductor chip including the X8-bit structure, and the third semiconductor chip including a plurality of third data pads on an upper surface thereof;
a fourth semiconductor chip disposed between the first semiconductor chip and the second semiconductor chip, the fourth semiconductor chip including the X8-bit structure, and the fourth semiconductor chip including a plurality of fourth data pads on an upper surface thereof;
a fifth semiconductor chip on the third semiconductor chip, the fifth semiconductor chip including the X16-bit structure, and the fifth semiconductor chip including a plurality of fifth data pads on an upper surface thereof;
a sixth semiconductor chip on the fifth semiconductor chip, the sixth semiconductor chip including the X8-bit structure, and the sixth semiconductor chip including a plurality of sixth data pads on an upper surface thereof;
a plurality of first connection members connecting some of the plurality of first connection pads and some of the plurality of first data pads;
a plurality of second connection members connecting the plurality of first connection pads and the plurality of second data pads;
a plurality of third connection members connecting some of the plurality of second data pads and some of the plurality of third data pads;
a plurality of fourth connection members connecting some of the plurality of second connection pads and some of the plurality of fourth data pads;
a plurality of fifth connection members connecting the plurality of second connection pads and the plurality of fifth data pads; and
a plurality of sixth connection members connecting some of the plurality of fifth data pads and some of the plurality of sixth data pads.

13. The semiconductor package of claim 12, wherein
the plurality of first connection pads are disposed at a first side of the first semiconductor chip, and
the plurality of second connection pads are disposed at a second side that is opposite to the first side of the first semiconductor chip.

14. The semiconductor package of claim 12, wherein
the fourth semiconductor chip is stacked on the first semiconductor chip and offset to expose the plurality of first data pads.

15. The semiconductor package of claim 12, wherein
the second semiconductor chip is stacked on the fourth semiconductor chip to fully overlap the first semiconductor chip in a plan view.

16. The semiconductor package of claim 12, wherein
the third semiconductor chip is stacked on the second semiconductor chip and offset to expose the plurality of second data pads.

17. The semiconductor package of claim 12, wherein
the fifth semiconductor chip is stacked on the third semiconductor chip and offset to expose the plurality of third data pads.

18. The semiconductor package of claim 12, wherein
the first semiconductor chip, the second semiconductor chip, the third semiconductor chip, the fourth semiconductor chip, the fifth semiconductor chip, and the sixth semiconductor chip each further include a plurality of auxiliary pads, and
some of the plurality of auxiliary pads of each of the first semiconductor chip, the second semiconductor chip, the third semiconductor chip, the fourth semiconductor chip, the fifth semiconductor chip, and the sixth semiconductor chip are command/address pads.

19. The semiconductor package of claim 12, wherein
the first semiconductor chip includes a buffer chip, and
the second semiconductor chip, the third semiconductor chip, the fourth semiconductor chip, the fifth semiconductor chip, and the sixth semiconductor chip each include a memory semiconductor chip, respectively.

20. The semiconductor package of claim 12, wherein
each of the plurality of first data pads, the plurality of third data pads, the plurality of the fourth data pads, and the plurality of the sixth data pads include a plurality of non-functional pads.
